(19) United States
(12) Patent Application Publication
(10) Pub. No.: US 2010/0313933 A1
(43) Pub. Date: Dec. 16, 2010

(54) Reflector-solar receiver assembly and solar module

(75) Inventor: Jianguo Xu, Wrightstown, PA (US)

Correspondence Address: Jianguo Xu, 131 Fox Hill Drive, Wrightstown, PA, 18940, US

(73) Assignee: Jianguo Xu, Wrightstown, PA (US)

(21) Appl. No.: 12/860,855

(22) Filed: Aug. 20, 2010

Related U.S. Application Data
(63) Continuation of application No. PCT/US2009/001121, filed on Feb. 21, 2009.
(60) Provisional application No. 61/030,449, filed on Feb. 21, 2008.

(51) Int. Cl. H01L 31/052; H01L 31/04; B23P 11/00

(52) U.S. Cl. 136/246; 136/259; 29/428

(57) ABSTRACT

A reflector-solar receiver assembly and methods related to the reflector-solar receiver assembly are described. The reflector-solar receiver assembly contains a reflector and a solar receiver. The reflector has a substantially planar light reflecting face and the solar receiver has a substantially planar light receiving face. The normal direction of the light reflecting face and the normal direction of the light receiving face are at an angle of about 90°. The reflector-solar receiver assembly can be installed at an installation site by placing the substantially planar light reflecting face at an angle of about γ−23.5° or about γ+23.5° from the gravitation line of the installation site, γ is the latitude of the installation site, so that the substantially planar light reflecting face reflects at least a portion of sunlight to the substantially planar light receiving face during a majority of the clear days of a year.

### CROSS-REFERENCE TO RELATED APPLICATIONS

This application is a Continuation of International Application No. PCT/US2009/001121, filed Feb. 21, 2009, which was published in English on Aug. 27, 2009, under International Publication No. WO/2009/105268, and the disclosure of which is incorporated herein by reference.

### BACKGROUND OF THE INVENTION

It is known that mirrors can be used to boost the performance of solar panels by directing to the solar panels sunlight that would otherwise not be received by the solar panels. However, as sunlight varies in its incidence angle, mirrors may lose their effectiveness in reflecting the sunlight to the solar panels. In addition, hot spots may be generated when a certain area of the solar panels receives much more than normal sunlight. Consequentially, mirror boosters have not been widely used in photovoltaic (PV) power generation systems.

There is a need for an improved reflector-solar receiver that increases the performance of solar panels during a majority of the clear days of a year while avoiding the hot spot problem. The present invention meets such need.

### BRIEF SUMMARY OF THE INVENTION

In one general aspect, the present invention relates to a reflector-solar receiver assembly, which comprises a reflector and a solar receiver. The reflector has a substantially planar light reflecting face, the solar receiver has a substantially planar light receiving face. The normal direction of the substantially planar light reflecting face and the normal direction of the substantially planar light receiving face are at an angle of about 90°.

In a preferred embodiment, the present invention relates to a solar panel-reflector module (SPRM). The SPRM comprises at least two of the reflectors and two of the solar receivers. The solar receivers are photovoltaic cells, photovoltaic panels, or combinations thereof.

In another general aspect, the present invention relates to a method of installing a reflector-solar receiver assembly that comprises a reflector having a substantially planar reflecting face and a solar receiver having a substantially planar light receiving face at an installation site on Earth. The method comprises placing the substantially planar light reflecting face at an angle of about γ−23.5° or about γ+23.5° from the gravitation line of the installation site, where γ is the latitude of the installation site, so that the substantially planar light reflecting face reflects at least a portion of sunlight to the substantially planar light receiving face during a majority of the clear days of a year.

In another general aspect, the present invention relates to a method of installing a reflector-solar receiver assembly according to embodiments of the invention at an installation site on Earth. The method comprises placing the normal line of the substantially planar light receiving face at an angle of about γ−23.5° or about γ+23.5° from the gravitation line of the installation site, where γ is the latitude of the installation site, so that the substantially planar light reflecting face reflects at least a portion of sunlight to the substantially planar light receiving face during a majority of the clear days of a year.

Other aspects, features and advantages of the invention will be apparent from the following disclosure, including the detailed description of the invention and its preferred embodiments and the appended claims.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 illustrates a reflector-solar receiver assembly (10) according to an embodiment of the present invention;

FIG. 2 illustrates an reflector-solar receiver assembly (15) according to an embodiment of the present invention;

FIG. 3 illustrates a solar panel-reflector module (SPRM) (20) according to an embodiment of the present invention;

FIG. 4 illustrates a SPRM (30) according to an embodiment of the present invention, which comprises more than one reflector-solar receiver assemblies that comprise two solar receivers (2a and 2b) facing different directions;

FIG. 5 illustrates a SPRM (40) according to an embodiment of the present invention, which comprises a bifacial solar cell (4) and a combination of planar reflectors (3a1 and 3a2) and a cylindrical trough reflector (3b);

FIG. 6 illustrates a method of installing a SPRM (20) according to an embodiment of the invention, wherein the normal direction (5) of a solar receiver (2) is parallel to the sunlight (6) at noon on Winter Solstice;

FIG. 7 is a comparison of a reflector-solar receiver assembly (10) installation according to an embodiment of the invention with a prior art solar panel (50) installation at Winter Solstice;

FIG. 8 is a comparison of a reflector-solar receiver assembly (10) installation according to an embodiment of the invention with a prior art solar panel (50) installation at the Spring or Autumn Equinox;

FIG. 9 is a comparison of a reflector-solar receiver assembly (10) installation according to an embodiment of the invention with a prior art solar panel (50) installation at Summer Solstice;

FIG. 10 illustrates a method of installing a SPRM (150) according to an embodiment of the present invention at a latitude of 40° in the northern hemisphere of the Earth;

FIG. 11 illustrates a method of installing a SPRM (20) according to an embodiment of the present invention on top of a building (100) at a latitude of 40° in the northern hemisphere of the Earth;

FIG. 12 illustrates a SPRM (20) according to an embodiment of the present invention at Summer Solstice, Spring or Autumn equinox, and Winter Solstice, wherein the normal direction of a solar receiver (2) is parallel to the sunlight (8) at noon on Summer Solstice;

FIG. 13 illustrates a method of installing a SPRM (20) according to an embodiment of the present invention on a southern side wall of a building;

FIG. 14 illustrates a method of installing a SPRM (20) according to an embodiment of the present invention on a rooftop at a latitude higher than 20.5° in the northern hemisphere of the Earth;

FIG. 15A illustrates an installation of a SPRM (20) on a horizontal surface at a latitude higher than 20.5° in the northern hemisphere of the Earth, wherein small amounts of reflected sunlight (6) are lost into space on and near Summer Solstice;

FIG. 15B illustrates an installation of a SPRM (60) on a horizontal surface at a latitude higher than 20.5° in the northern hemisphere of the Earth, wherein on non-Winter Solstice days, small amounts (6) of sunlight are lost in gaps (9) created for maintenance of the SPRM (60);

FIG. 16 illustrates a method of installing a SPRM (30) on a pitch roof according to an embodiment of the invention, wherein the SPRM (30) that has at least two solar panels (2a and 2b), and wherein the normal directions of the solar panels (2a and 2b) are parallel to the sunlight (8 and 6) at noon on Summer Solstice and Winter Solstice, respectively;

FIG. 17 illustrates a SPRM 200 wherein the reflector 201 is made of an acrylic plate with parallel ridges on a side 201a that is 90° from the substantially planar light receiving face of the solar receiver 202;

FIG. 18A illustrates an installation of a SPRM according to an embodiment of the present invention on a gas station at a latitude of 40° in the northern hemisphere of the Earth; and

FIG. 18B illustrates a prior art installation of conventional solar panels on a gas station at a latitude of 40° in the northern hemisphere of the Earth.

### DETAILED DESCRIPTION OF THE INVENTION

Unless defined otherwise, all technical and scientific terms used herein have the same meaning as commonly understood to one of ordinary skill in the art to which this invention pertains. Otherwise, certain terms used herein have the meanings as set in the specification. All patents, published patent applications and publications cited herein are incorporated by reference as if set forth fully herein. It must be noted that as used herein and in the appended claims, the singular forms “a,” “an,” and “the” include plural reference unless the context clearly dictates otherwise.

As used herein, a “reflector” refers to an optical device that has a reflecting surface that reflects light. Examples of a reflector include mirrors of various shape and form, including, but not limited to, flat mirrors, mirrors formed of spherical surfaces, or cylindrical surfaces, and reflective surfaces that have somewhat less reflective efficiency than the conventional mirrors, such as a thin aluminum sheet with a protection layer on its top, as well as reflectors due to internal reflection, such as those comprise one or more clear materials. In the context of the present patent, a reflector is considered to be “one” reflector if the geometric form of its light reflecting face can be described by a simple mathematical equation. If the geometric form of the light reflecting face of a reflector body can only be described by two or more simple mathematical equations, the reflector body is considered to comprise two or more reflectors. For example, if a segment of the light reflecting face of a reflector body can be expressed by a linear function while the other segment of the light reflecting face of the reflector body can be expressed by that of a cylindrical trough, this reflector body is considered to comprise two reflectors, even if the light reflecting surface of the reflector body is a smooth compound surface. Ideally, a perfect reflector has no losses of light, and a perfect reflecting surface precisely follows a desired mathematical description or an ideal design.

As used herein, a “clear material” is a material that is substantially transparent to solar radiation.

As used herein, “normal direction” of a surface refers to the normal line of the surface, i.e., the line that is at a right angle with the surface, that has a direction pointing away from the surface.

As used herein, the direction of the gravitational line points to the gravitational center of the Earth.

As used herein, a “solar receiver” or “solar panel” refers to a light receiving device that comprises at least a solar cell. The solar receiver can receive and convert light via photovoltaic energy conversion process. The light receiving face of a solar receiver is capable of receiving light from all sources, including that directly from the sun or that indirectly from a reflector, and facilitating the use of the light received for an intended purpose.

As used herein “Solstice” means the day when the site of installation of the solar energy generating system is oriented closest towards or furthest away from the Sun. For Northern Hemisphere, “Winter Solstice” refers to the solstice in December, when the sun is directly over the Tropic of Capricorn in the Southern Hemisphere. “Summer Solstice” refers to the solstice in June, when the sun is directly over the Tropic of Capricorn in the Northern Hemisphere. For Southern Hemisphere, the order is reversed in the context of the present application.

As used herein a “bifacial solar receiver” or “bifacial solar panel” refers to a class of photovoltaic cell or solar panel that has two substantially planar light receiving faces and the normal directions of the two substantially planar light receiving faces of a bifacial solar panel are about 180° from each other. Bifacial solar receivers can be made using methods known in the art or are commercially available from companies, such as Sanyo, Hitachi, etc.

As used herein, the phrase “substantially at an angle of α,” “at an angle of about α” or an expression similar thereto includes any angle of the value α or the value α−α₁ to α+α₁, wherein α₁ is less than about 20% of α, for example, less than about 15%, about 10%, or about 5% of α. Depending on the context of the phrase, the maximum value of α₁ to be allowed in an embodiment of the present can be determined using methods known in the art in view of the present disclosure.

As used herein, “in contact” or “contact” when used to describe the relative locations of two objects means that the two objects are adjacent to each other in close proximity. In one embodiment of the present invention, when two objects are in contact or contact with each other, they touch or connect with each other without having any physical gap between the two objects. The gap-less contact is used when seamless connection or junction is preferred, for example, when more than one reflectors are in contact with each other to form a compound reflective surface. In another embodiment of the present invention, when two objects are “in contact” or “contact with each other”, there is a physical gap between the two objects. The gap-existing “contact” is preferred when there is a need to prevent the accumulation of debris, such as rain, snow, leaves, dirt and dust, etc., at the junction or contacting point between the two objects, for example, between a reflector and a solar-receiver in a solar module.

In one general aspect, the present invention relates to a reflector-solar receiver assembly, that comprises a reflector and a solar panel, wherein the reflector has a substantially planar light reflecting face, the solar receiver has a substantially planar light receiving face, and the normal direction of the substantially planar light reflecting face and the normal direction of the substantially planar light receiving face are at an angle of about 90°.

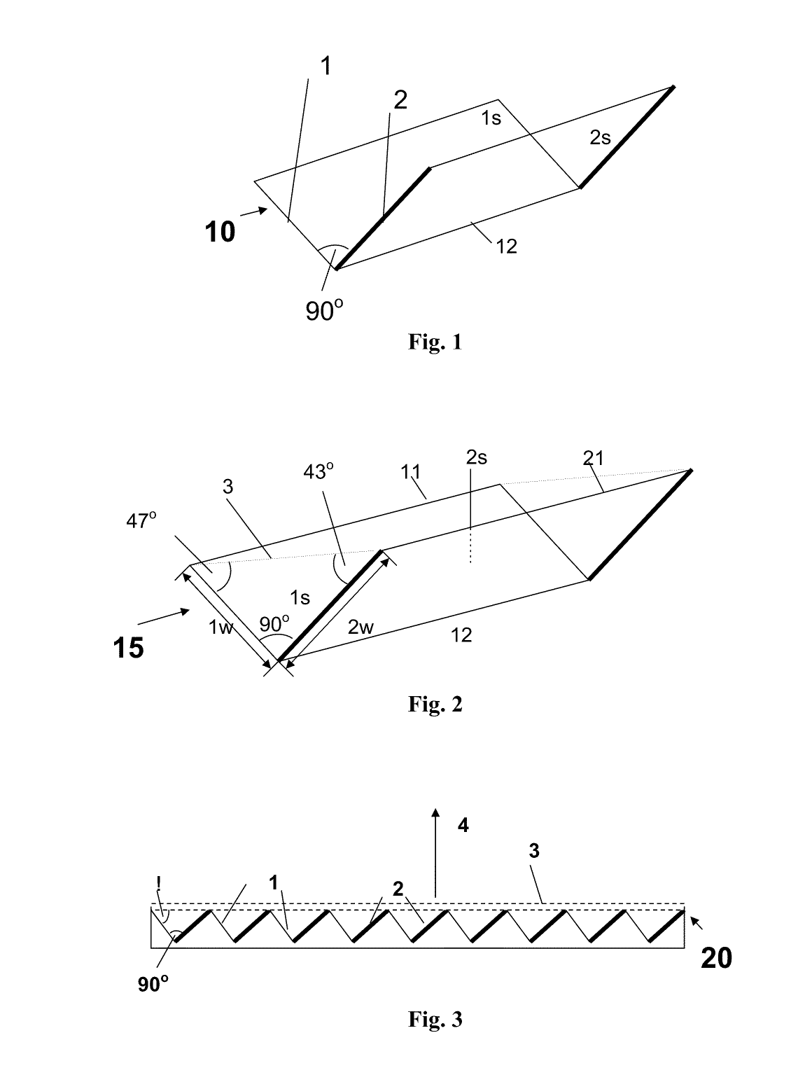

Referring to FIG. 1, a reflector-solar receiver assembly according to an embodiment of the present invention comprises a reflector 1 that has a substantially planar light reflecting face 1s, and a solar receiver 2 that has a substantially planar light receiving face 2s. The lower edges 12 of the faces 1s and 2s are placed in contact with each other. There can be a gap between the lower edges of the reflector and the solar receiver that prevents accumulation of debris in the assembly. The faces 1s and 2s are about 90° from each other.

Referring to FIG. 2, in an embodiment of the present invention, face 1s and face 2s are substantially at angles of 47° and 43°, respectively, with a top plane 3, which is formed by the top edges, 11 and 21, of face 1s and face 2s, respectively. The appropriate angles can be obtained by coordinating the ratio of the width 1w of the light reflecting face 1s to that 2w of the light receiving face 2s to cos 47°/cos 43°=0.93.

Referring to FIG. 3, an embodiment of the present invention relates to a solar panel-reflector module (SPRM) 20, which comprises multiple reflector-solar receiver assemblies according to an embodiment of the present invention. The SPRM 20 optionally includes a top protection layer 3 covering the reflectors 1 and solar panels 2 of the assemblies. The top protection layer 3 can help preventing the collection of debris in the SPRM 20, but may cause some losses of light due to reflection. The top protection layer 3 can also protect the components inside the SPRM from being exposed to moisture. The top protection layer 3 can be made of a transparent material, such as glass or plastic.

In a preferred embodiment, a substantially planar light reflecting surface of the reflector 1 is substantially at an angle α of 47° with the top protection layer 3. The normal direction of SPRM 20 refers to the normal direction of the top plane formed by the top edges of the reflectors and the top edges of the solar panels in the SPRM 20, which is shown as arrow 4 in FIG. 3. This top plane is also referred to as the light receiving face of the SPRM 20.

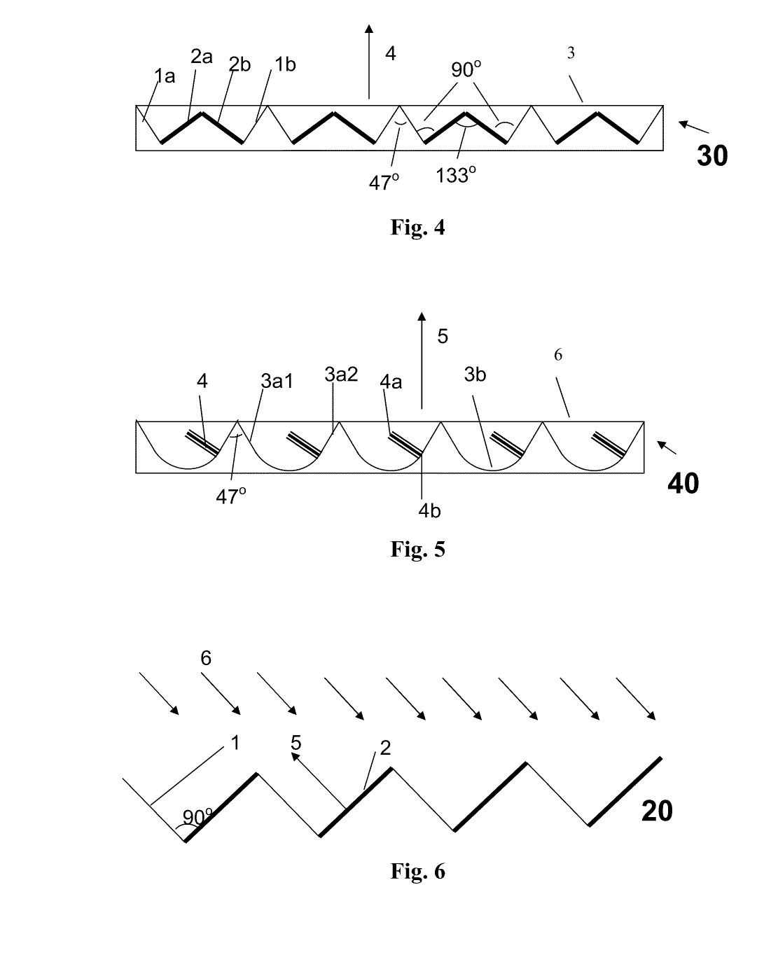

In another embodiment, as illustrated in FIG. 4, a SPRM 30 comprises at least two reflector-solar receiver assemblies, each of which contains two solar receivers, 2a and 2b, facing different directions. Each of the solar receivers contains a substantially planar light receiving face. Each of the reflector-solar receiver assembly also comprises at least two reflectors, 1a and 1b, facing different directions. Each of the reflectors contains a substantially planar light reflecting face. The normal directions of the substantially planar light receiving faces and the normal directions of the substantially planar light reflecting face are at an angle of about 90° from each other, respectively. The normal direction of SPRM 30 refers to the normal direction of the top plane, 3, formed by the top edges of the reflectors, 1a and 1b, which is illustrated as arrow 4 in FIG. 4. This top plane, 3, is also referred to as the light receiving face of the SPRM 30.

In a preferred embodiment, the at least two solar receivers, 2a and 2b, are adjacent to each other and their normal directions are substantially at an angle (α) of 47°. In another preferred embodiment, the at least two reflectors, 1a and 1b, are adjacent to each other and their normal directions are substantially at an angle of 133°.

In an embodiment, the present invention also relates to a reflector-solar receiver assembly comprising a solar receiver that is a bifacial solar cell having two substantially planar light receiving faces. The assembly also comprises two reflectors, each of which having a substantially planar light reflecting face. The normal directions of the substantially planar light reflecting faces of the two reflectors are substantially 133° from each other.

FIG. 5 illustrates a SPRM 40 according to an embodiment of the present invention. SPRM 40 comprises a bifacial solar panel 4. It also comprises a compound light reflector, which is formed by the combination of a first planar reflector 3a1, a cylindrical trough reflector 3b and a second planar reflector 3a2. The cross section of the cylindrical trough reflector 3b is a circular arc of substantially 133°. As shown in FIG. 5, each cylindrical trough reflector 3b is substantially tangential to the two planar reflectors 3a1 and 3a2. The normal directions of the first planar reflector 3a1 and the second planar reflector 3a2 are substantially at an angle of 133°. The normal direction of SPRM 40 refers to the normal direction of the top plane, 6, formed by the top edges of the reflectors 3a1 and 3a2 in SPRM 40, which is shown as arrow 5 in FIG. 5. The top plane, 6, is also referred to as the light receiving face of the SPRM 40.

In a preferred embodiment, the top edge 4a of the bifacial solar panel 4 is on the centerline of the cylindrical trough reflector 3b, and the lower edge 4b of the bifacial solar panel 4 is in contact with the cylindrical trough reflector 3b. The edge 4b can be in contact with the cylindrical trough reflector 3b of any angle on the arc.

In another general aspect, the present invention relates to a method of installing a reflector-solar receiver assembly, which has a reflector having a substantially planar reflecting face and a solar receiver having a substantially planar light receiving face. The method comprises, at an installation site on Earth, placing the substantially planar light reflecting face of the reflector at an angle of about γ−23.5° or γ+23.5° from the gravitation line of the installation site, where γ is the latitude of the installation site and 23.5° is the tilt of the polar axis of the Earth, so that the substantially planar light reflecting face reflects at least a portion of sunlight to the substantially planar light receiving face during a majority of the clear days of a year.

In a preferred embodiment, the present invention relates to a method of installing the reflector-solar receiver assembly such that the normal direction of a substantially planar light receiving face of the solar receiver of the reflector-solar receiver assembly is substantially 180° from the sunlight at noon on either Winter Solstice or Summer Solstice day.

In another embodiment, the reflector-solar receiver assembly is a reflector-solar receiver assembly according to embodiments of the present invention.

FIG. 6 is a schematic diagram of a method of installing a SPRM 20 according to an embodiment of the invention. SPRM 20 is installed such that a substantially planar reflecting face of the reflector 1 is parallel to the sunlight at noon on Winter Solstice day. In other words, the reflecting face of the reflector 1 is at an angle of γ+23.5° from the gravitational line.

In FIG. 6, in a preferred embodiment, the normal direction 5 of a substantially planar light receiving face of a solar receiver 2 is parallel to the sunlight 6 at noon on Winter Solstice. The orientation of the SPRM 20 is such that the angle between the gravitational line at the installation site and the normal direction of the substantially planar light receiving face of the solar receiver 2 is substantially equal to γ+23.5°. The normal direction of the substantially planar reflecting face of the reflector 1 and the normal direction of the substantially planar light receiving face of the solar receiver 2 are at an angle of about 90°. The lower edges of the reflectors 1 are in contact with those of the solar receivers 2. Preferably, there is a gap between the reflector 1 and the solar receiver 2 to prevent the collection of debris.

While placing the reflector and the solar receiver at a right angle from each other is optimal for a new solar energy installation, using such an option in existing plants may involve altering the original supporting structure for the solar panels, which may be costly. In one embodiment of the present invention, a method is provided to retrofit an existing photovoltaic power plant installed on a substantially horizontal surface, wherein the solar panels are installed in such a way that the normal direction of the solar panels are tilted at an angle of γ (γ is equal to the latitude of the installation site) from the gravitational line. The method comprises installing a reflector to the existing solar panel installations, so that the reflector is parallel to sunlight at noon on the Winter Solstice day, with the sunlight reflected by the reflector pointing towards the polar side (north on northern hemisphere, and south on southern hemisphere), and that the lower edge of the reflector is substantially in contact with the lower edge of the solar panel. Although such a method of installing the reflector-solar panel assembly does not minimize the area of solar panel, the original supporting structure of the solar panels does not have to be altered, which may be optimal in certain places. Again, a gap can be included between the lower edges of the reflector and solar panel to prevent the collection of debris.

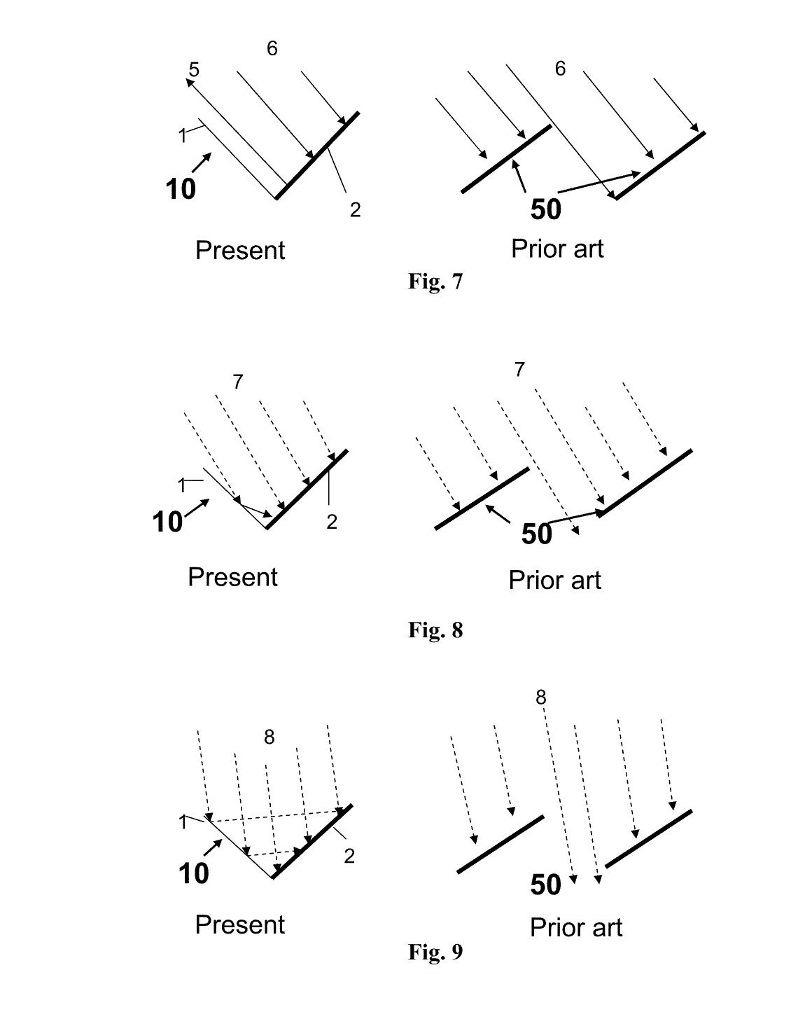

FIGS. 7-9 illustrate comparisons of a reflector-solar receiver assembly 10 installation according to an embodiment of the invention with a prior art solar panel 50 installation on a horizontal surface. FIG. 7 is the comparison at Winter Solstice. In an example, when the reflector-solar receiver assembly 10 is installed using a method according to an embodiment of the present invention, the angle between the gravitational line at the installation site and the normal direction 5 of a substantially planar light receiving face of the solar receiver 2 is substantially equal to γ+23.5°, and the normal direction 5 is at an angle of about 180° from the sunlight 6 at noon on Winter Solstice. In another example, when the prior solar panel 50 is installed using a conventional method, the orientation of the multiple solar panels is such that the angle between the gravitational line at the installation site and the normal direction of the solar panel is substantially equal to γ, and that the normal direction of the light receiving face of the solar panel is at an angle of about 180°-23.5° from the sunlight at noon on Winter Solstice.

To cover the same horizontal area, the substantially planar light receiving face of the solar receiver 2 in the assembly 10 installed by the method of the present invention is cos 23.5°×100%=92% of the light receiving face of the prior art solar panel 50 installed by the conventional method, assuming that no shade is formed on the solar panels and all incident direct sunlight hits the solar panels directly or via a reflector in both the reflector-solar receiver assembly 10 and the conventional design 50.

FIG. 8 is the comparison at Spring or Autumn Equinox, when the Sun is positioned directly over the Earth's equator. In an example, when the reflector-solar receiver assembly 10 is installed using a method according to an embodiment of the present invention, at noon on Spring or Autumn Equinox, the normal direction of the substantially planar light receiving face of the solar panel 2 is about 180°-23.5° from the sunlight 7, because the normal direction is at an angle of about 180° from the sunlight 6 at noon on Winter Solstice. Some of the sunlight hits the reflector 1, e.g., a mirror, and is reflected to the solar receiver 2. All of the direct sunlight either directly hits the solar receiver 2 or is reflected by the reflector 1 (if it is a perfect reflector) to the solar receiver 2 within the reflector-solar receiver assembly 10. On the other hand, in another example, the prior solar panels 50 are installed using a conventional method. The normal direction of the light receiving face of the solar panel in the conventional design is at an angle of 180° from the sunlight. Some sunlight misses the solar panel in the conventional design.

FIG. 9 is the comparison at Summer Solstice. In an example, when the reflector-solar receiver assembly 10 is installed using a method according to an embodiment of the present invention, at noon on Summer Solstice, the normal direction of the substantially planar light receiving face of the solar panel 2 is about 133° from the sunlight 8, because the normal direction is at an angle of about 180° from the sunlight 6 at noon on Winter Solstice. More direct sunlight is reflected by the reflector 1 to the solar panel. On the other hand, in another example, the prior solar panels 50 are installed using a conventional method. More direct sunlight would miss the solar panels if the installation of the solar panels is such that no area of the solar panels is shaded on Winter Solstice.

A preferred reflector-solar receiver assembly according to the present invention is the assembly 15 illustrated in FIG. 2. The assembly captures all the sunlight that hits the reflector-solar panel assembly, either by receiving the sunlight that reaches directly to the solar receiver 2, or by receiving the sunlight that is reflected by the reflector 1 to the solar receiver 2.

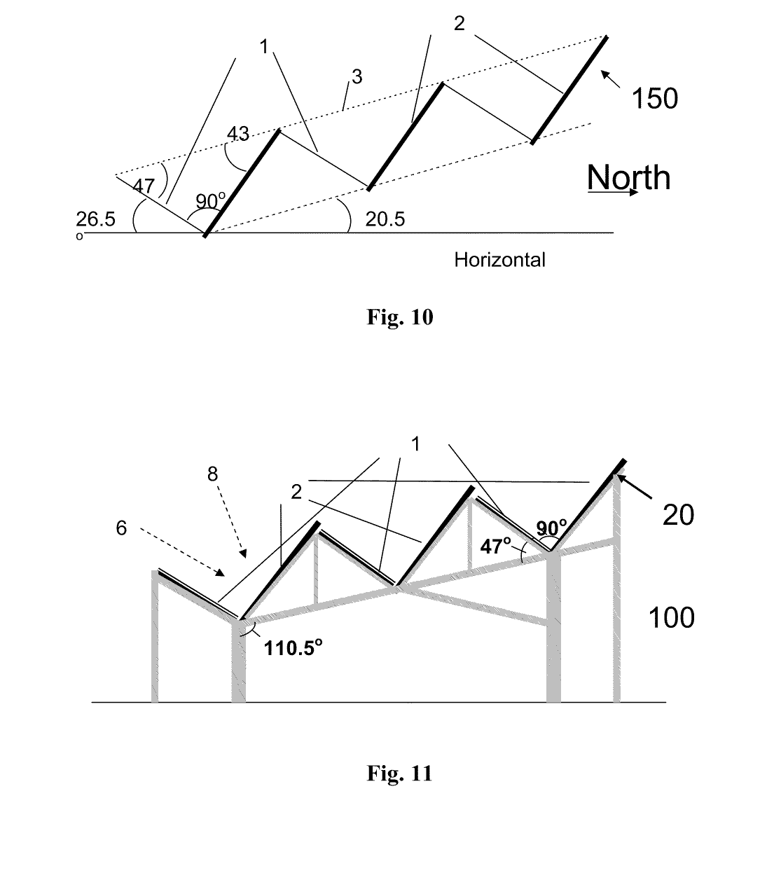

FIG. 10 illustrates a method of installing a SPRM 150 comprising multiple reflector-solar receiver assemblies 15 according to an embodiment of the present invention at latitude of 40° in the northern hemisphere of the Earth. If the latitude of the installation site for the SPRM 150 is greater than about 19.5°, the entire SPRM 150 will have to be installed in a tilted way similar to the seat arrangement in a theater in order to use all the incident direct sunlight. For example, if the latitude of the power plant, i.e., the installation site, is 40 degrees in the northern hemisphere, such as that in Philadelphia, Pa. and Denver, Colo., the optimal installation angle of the SPRM a50 is shown in FIG. 10: SPRM 150 is installed at such a location such that the light receiving face of SPRM 150 is tilted about 20.5° from the horizontal line, or the normal direction of SPRM 150 is tilted from the gravitational line at an angle of 20.5°. The light receiving face of SPRM 150 is the top plane 3 formed by the top edges of the reflectors 1 and receivers 2. The normal direction of SPRM 150 is the normal direction of the top plane 3.

The tilted angle of SPRM 150 can be calculated by the following formula:

Tilt angle=47°−(90°−latitude−23.5°)=latitude−19.5°(when the tilt angle is greater than 0°)

When the normal direction of a substantially planar light receiving face of a solar panel of the SPRM is 180° from the sunlight at noon on Winter Solstice, the power generated from the solar PV plant using the present invention is in theory equal to that with conventional design but involves less light receiving face of the solar panels on Winter Solstice. The power generated from the solar PV plant using the present invention is more than that with conventional design on the days other than Winter Solstice, even with 8% less solar panel area. For example, at noon of Summer Solstice day, the amount of light received by the solar panels using the present invention is in theory close to 50% more than that from the conventional PV power plant for most locations in industrialized nations. In practice, some of the light hitting a solar panel or reflector does not come directly from the Sun and some of this diffuse light can be from angles that do not allow the reflected light to reach the solar panel, so the practical difference at noon of Summer Solstice day is somewhat smaller than 50%.

In addition, at a higher concentration of light, the efficiency of the solar cell is generally increased when the temperature of the solar cell is held constant. In the present invention, the intensity of sunlight hitting any area of the solar panel due to the direct sunlight and the sunlight reflected from the reflector is always below two suns. In addition, the heat dissipation rate from the solar cells of the solar modules of the present invention can be increased in order to keep the temperature of the solar cells at the desirable value.

The much increased solar power output in summer is particularly desired. More sunlight is available in summers, especially at noontime. The sunshine time is longer and the sunlight is typically stronger in the summer, because the light does not have to travel through as a thick layer of atmosphere as in the other seasons, and the summer sky is typically less cloudy in many locations. In addition, the demand for electricity is stronger during summer days, especially summer afternoons due to the peak demand for electricity from air conditioning applications. The intensity of direct sunlight hitting the solar panel of the SPRM of the present invention is about 1.49 suns with a perfect reflector at noon of Summer Solstice day.

In an embodiment of the present invention, the reflector-solar receiver assembly or the SPRM according to embodiments of the present invention can be installed together with a one-dimensional tracker, preferably, the “polar” or “azimuth” type. An additional advantage of using an azimuth tracker is in that the height of the system does not change with time of the day and can be very low, thereby results in a lower peak wind load than the systems on other types of trackers. Such low profile azimuth tracker can also be supported on a bigger area, resulting in much reduced stress and/or torque at the base of the tracker. Therefore, azimuth trackers are recommended for use with the reflector-solar receiver assembly or the SPRM according to embodiments of the present invention, especially those shown in FIGS. 6, 15a, and 15b. Such a system may be particularly suitable for application on commercial rooftops and other leveled fields.

The reflector-solar receiver assembly or the SPRM according to embodiments of the present invention can be manufactured and installed by various means. FIG. 11 shows an aesthetically pleasing and mechanically desirable design of the rooftop of a commercial building 100 that incorporates the present invention at an installation site at 40° latitude. In the figure, the Winter Solstice day sunlight 6 is shown to be at right angle with respect to the solar receiving face of the solar panels 2, and parallel to the substantially planar reflecting face of the reflectors 1.

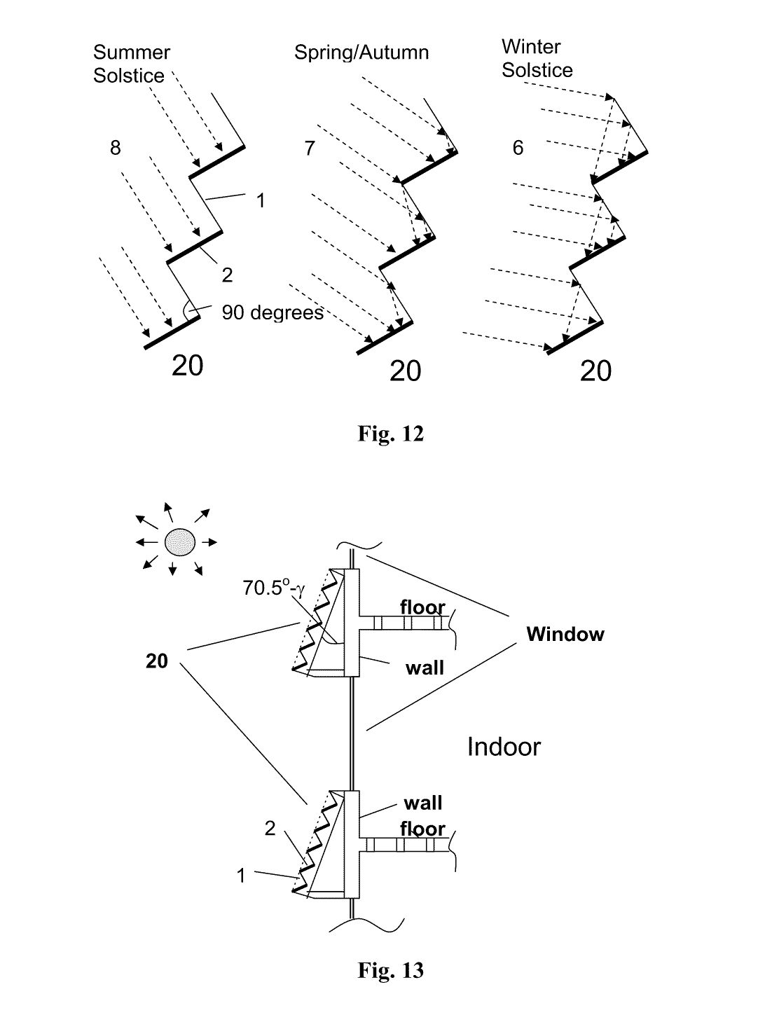

As described above, the normal direction of a light receiving face of the solar panel of the reflector-solar receiver assembly can be 180° from the sunlight at noon on either Winter Solstice or Summer Solstice. FIG. 12 illustrates the installation of a SPRM 20 with the noon sunlight 8 on Summer Solstice at about right angle to the light receiving face of the solar panels and about parallel to the reflectors. As shown in FIG. 12, no shade is formed on the solar panels and all incident direct sunlight hits the solar panels on Summer Solstice day. Also as shown in FIG. 12, at noon on Spring or Autumn Equinox, the normal direction of the light receiving face of the solar panel 2 is about 180°-23.5° from the sunlight 7 and some of the sunlight hits the reflector 1 and is reflected to the solar panel 2. All of the direct sunlight either directly hits the solar panel or is reflected by the reflector to the solar panel within the SPRM 20. FIG. 12 further shows that, at noon of Winter Solstice, the normal direction of the light receiving face of the solar panel 2 is about 133° from the sunlight 6 and more direct sunlight is reflected by the reflector to the solar panel.

FIG. 13 illustrates the application of a SPRM according to an embodiment of the present invention on a building wall facing south in Northern Hemisphere or north in Southern Hemisphere. For an optimal installation, the angle between the wall and the SPRM can be substantially the same as the angle between the gravitational line and the normal direction of the SPRM, which is approximately equal to 70.5°−γ, wherein γ is the latitude of the installation site. As used herein “the normal direction of the SPRM” refers to the normal direction of a plane formed by the top edges of the solar receivers and reflectors. This top plane will also be referred as the light receiving face of the SPRM hereafter. The tilt of the SPRMs not only is optimal for power generation, it also provides summer shade for the windows below them, which may be very desirable in summer months.

Because both the solar panel and the reflector in the SPRM have downward slopes that face outwards, no water would be collected in the SPRM. It is also difficult for solid debris to be collected in the SPRM even without a top plate. Therefore, the optional top plate is not necessary for the SPRMs to be installed on the wall. However, the top plate may be desirable if no protective coating is used on top of the reflective surface of the reflector, and if the surface of the solar panel is dimpled or otherwise made rougher to improve its light-trapping efficiency.

Note that the SPRM of FIG. 13 can also be installed on a pole, such as a utility pole or another vertical structure, such as that of a highway sign.

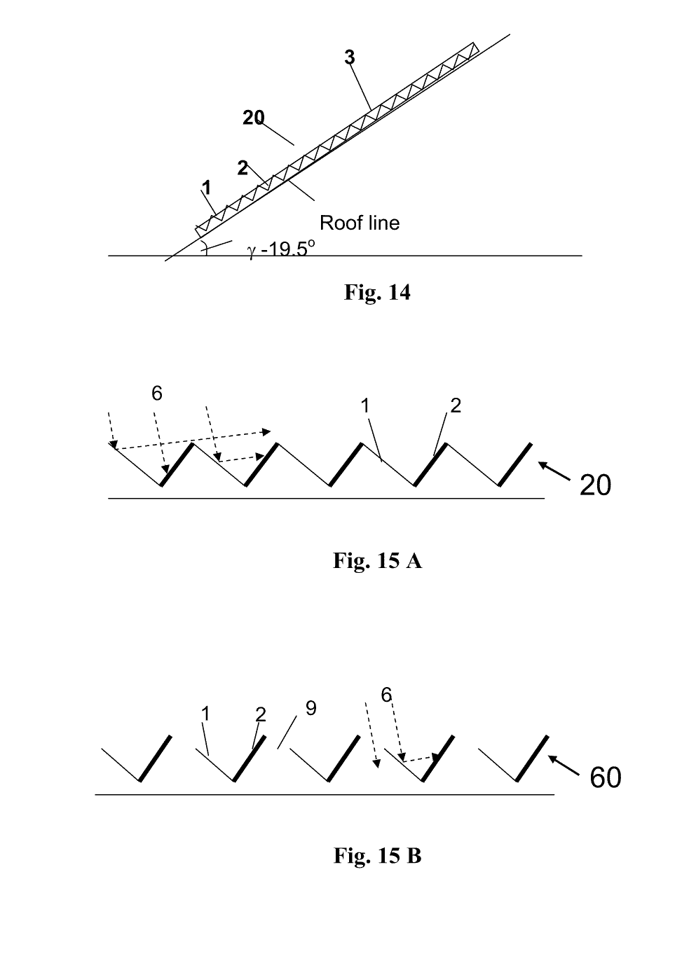

FIG. 14 illustrates the application of a SPRM 20 on a pitched roof. In this example, debris is more likely to collect on the solar cell without a top plate, so a top plate may be desirable. The optimal angle to be tilted is approximately γ−19.5°, wherein γ is the latitude of the site of installation of the SPRM. The design scheme shown in FIG. 14 is considered “optimal”, because the design allows the use of all the sunlight.

In practice, the optimal design can be varied to accommodate the existing environment, landscape, conditions, etc. For example, the optimal γ−19.5° tilt may not be economically feasible when the SPRM is to be installed on an existing flat roof at high latitude. There are options that allow the SPRM to collect most, although not all, of the sunlight, while still minimizing the amount of solar cells used.

As shown in FIG. 15A, small amounts of reflected sunlight 6 are lost into space on and near Summer Solstice day when a SPRM 20 is installed on a horizontal surface at latitude higher than about 20°. Nevertheless, if the light reflecting face of the reflector extends from the bottom of the light receiving face of a first solar panel to the top of a second solar adjacent to it, the first solar panel can still receive all the direct sunlight reflected by the mirror on days that are further away from Summer Solstice. Such an arrangement can be optimal if the cost of the reflector is small in comparison with that of the solar panel. As a matter of fact, due to the relatively low cost of mirrors, the additional cost of the added mirror in FIG. 15A may be well worth the investment in a lot of places, because the such loss of light typically only occurs on the days near Summer Solstice, and the added area of the mirrors still boost the power output on other days of the year.

As shown in FIG. 15B, a passage or a gap 9 can be included for maintenance or other practical reasons. The gap 9 can be created by not extending the reflector from on solar panel to another. On non-Winter Solstice days, small amount of sunlight 6 may be lost in the gaps 9 when the SPRM 20 is installed on a horizontal surface at latitude higher than about 19.5°.

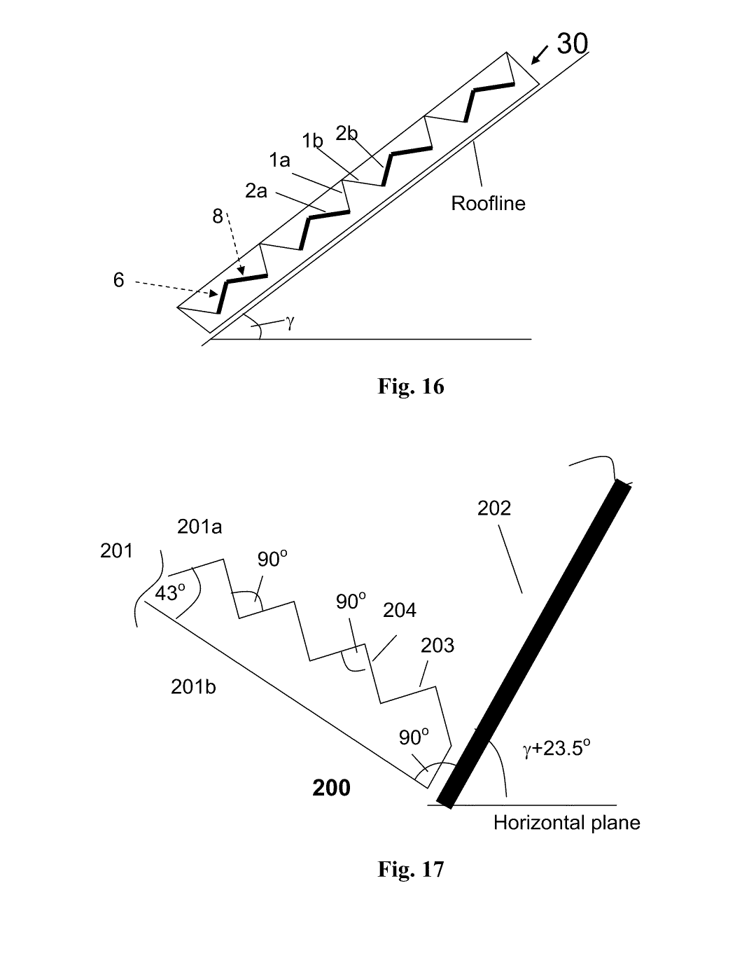

FIG. 16 illustrates a method of installing a SPRM 30 described above in reference to FIG. 4, on a pitch roof according to an embodiment of the invention. The SPRM 30 is installed on a pitched roof which has an angle from the horizontal plane (which is equivalent to the angle between the gravitational line and the normal direction of the roof) close to the latitude of the site. The SPRM 30 is installed such that the normal directions of the solar panels, 2a and 2b, are parallel to the sunlight (8 and 6) at noon on Summer Solstice and Winter Solstice, respectively. When there is no reflector loss, the area of the solar cell can in theory be reduced by 22.4% in comparison with the simple planar solar panels.

In another embodiment, a SPRM 40 described above in reference to FIG. 5 can be installed and used for solar power generation. The method of installing the SPRM 40 comprises placing substantially planar light reflecting faces of the two reflectors, 3a1 and 3a2, at an angle of about γ−23.5° and γ+23.5°, respectively, from the gravitation line of the installation site, where γ is the latitude of the installation site; and placing at least one of the substantially planar light receiving face of the solar panels such that it receives at least a portion of the sunlight directly from the direction of the Sun. Using such a solar module, the solar cell area can be further reduced by a factor of two as compared with that in FIG. 16.

In one embodiment of the present invention, the reflector used in the present invention comprises a clear material having a refractive index of greater than 1.33. The clear material does not have a typical metallic layer. The reflector further comprises a face having parallel ridges. Such a reflector can reflect light by internal reflection.

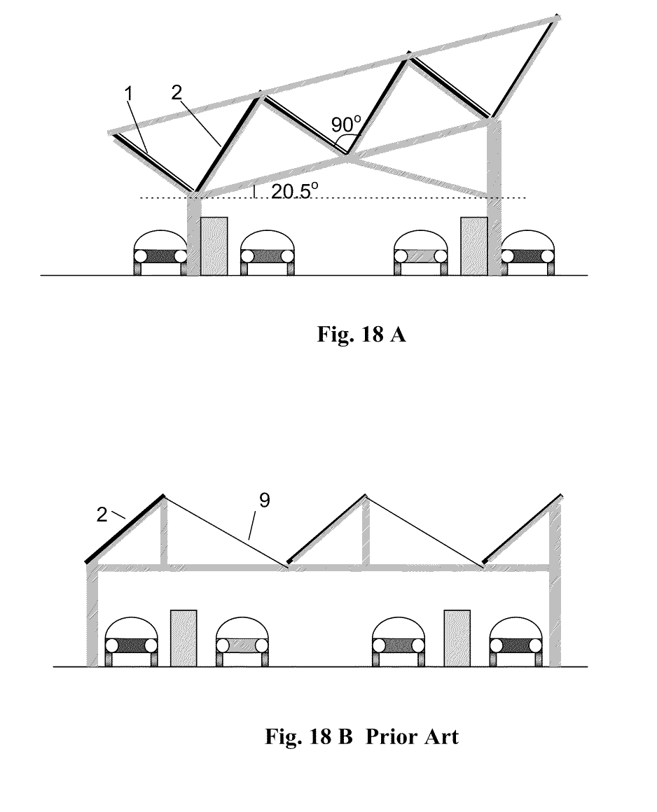

FIG. 17 illustrates a reflector-solar receiver assembly 200 according to an embodiment of the present invention, which has a reflector 201 and a solar receiver 202. The reflector 201 is made of a clear material, such as an acrylic plate, with parallel grooves (ridges) on a side, the ridged side 201a, facing directly to the solar panel (or module) 202 and a substantially planar back side 201b opposing to the ridged side 201a. Each of the grooves or ridges at the ridged side 201a has two facets: facet 203 facing up or away from the substantial planar light receiving face of the solar panel 202, and facet 204 facing directly the substantial planar light receiving face of the solar panel 202. The structure of the reflector 201 is such that a) the neighboring facets 203 and 204 of the ridged side 201a are about 90° from each other, b) the normal directions of the two facets are also about 90°, and c) facet 203 of the ridge that faces “away from” (facing up in the figure) the solar panel 202 is 43° from the back side 201b, which is substantially planar and is opposing to the ridged side 201a.

In an optimal design, the reflector 201 is placed together with the solar panel 202 in such a way that i) the (substantially planar) back side 201b of the reflector is 90° from the solar panel 202, ii) the lower edge of the reflector 201 is in contact with the lower edge of the solar panel (or module) 202, and iii) the facets 203 of the ridges facing away from the substantial planar light receiving face of the solar panel 202 are placed horizontally. The contact between the reflector 201 and the solar receiver 202 can be gap-existing contact to avoid the collection of debris.

A reflector similar to the acrylic plate 201 can be made with other clear materials, such as glass, polyvinylchloride, polycarbonate etc., and can be made at different thickness, e.g., 3 mm in thickness or thinner. It is not a reflector in the conventional sense—only the light coming from certain angles will be reflected since it relies on internal reflection to do its job. The refractive index of the material is significantly greater than 1, preferably in the range of 1.3 to 2, and more preferably in the range of 1.4 to 1.7. The angle between the neighboring facets of the ridged side can be smaller than 90 degrees, so can the normal directions of the two facets of a ridge. In addition, the 43 degree angle can also be changed. If this angle is decreased from 43 degrees, the angle between the two facets of the ridges can be somewhat greater than 90 degrees. However, such deviations are preferably not to exceed 5 degrees for a clear material with a refractive index of about 1.5.

This invention will be better understood by reference to the non-limiting examples that follow, but those skilled in the art will readily appreciate that the examples are only illustrative of the invention as described more fully in the claims which follow thereafter.

### Example

### A PV System Installed on the Top of a Gas Station

This example compares the performance of a reflector-solar receiver assembly according to an embodiment of the present invention with that of a conventional solar panel installed on the top of a gas station. The gas station is located at latitude of 40° in the northern hemisphere of the Earth. It has a plot area of 12 m×12 m covered with a canopy that is suitable for mounting solar panels. The canopy is to be designed according to the solar panel system design.

FIG. 18A illustrates an installation of a reflector-solar receiver assembly design according to an embodiment of the present invention on the gas station. The reflector-solar receiver assembly includes a solar panel 2 having a substantially planar light receiving face and a reflector 1 having substantially planar light reflecting face. The normal direction of the substantially planar light receiving face and the normal direction of the substantially planar light reflecting face are at about 90° from each other. The design and the installation of the reflector-solar receiver assembly is aesthetically pleasing and mechanically desirable, and is optimal for the solar power generation.

FIG. 18B illustrates a prior art installation of conventional solar panels 2 on the gas station. The conventional installation does not include a mirror booster, but allows all the sunlight on Winter Solstice to be fully used for power generation, and forms no shade anywhere on the solar panels any time.

In both designs, the solar panels face the equatorial sky (which means facing south in Northern Hemisphere or facing north in Southern Hemisphere). In the design illustrated in FIG. 18A, the normal direction of the substantially planar light receiving face of the solar panels is at an angle of γ+23.5° from the gravitational line of the site, and the reflector-solar receiver assembly in FIG. 18A is tilted γ−19.5°, wherein γ is the latitude of the installation site. In one example, when γ is 40°, the normal direction of the substantially planar light receiving face is 63.5° from the gravitational line of the site, and the reflector-solar receiver assembly is tilted 20.5° from the horizontal line.

In the prior art design illustrated in FIG. 18B, the normal direction of the solar panels is at an angle of 40°, the same as that of the latitude of the site, from the gravitational line.

In order to compare the performance of the two installations in FIGS. 17A and 18B, it is assumed that:

1). Reflector efficiency=95%

2). Solar panel efficiency=20%

3). Diffuse light is not considered

4). No credit is taken for the increased solar panel efficiency at higher solar radiation concentration

Table 1 shows the parameters and performance of the PV systems based on the present invention as shown in FIG. 18A and that based on the conventional design as shown in FIG. 18B. The productivity of the solar panel in the PV system in FIG. 18A is higher than that in FIG. 18B by 27%, 42% and 9% at noontime of Spring/Autumn Equinoxes, Summer Solstice, and Winter Solstice, respectively. The design in FIG. 18A also generates more power, partly because all the light that hits the roof is used for power generation, while the sunlight that hits the non-solar panel “roofing material” is considered lost in this analysis. There is a lot of the sunlight that hits the “roofing material” in summers.

In practice, a minor portion of the light that hits the roofing material in the system in FIG. 18B may actually be reflected to the solar panels by the roofing material if a reflective material is used for roofing, or if the roof is painted white. But that reflection is by far not as optimized as in the present invention. Besides, the effect of diffuse light and increased solar concentration can also have significant impact on the real performance the two systems and therefore the true difference in performance of the two systems.

TABLE 1
Parameters and noontime performance of the two PV systems

| PV System Design | FIG. 18A | FIG. 18B |
|---|---|---|
| The design parameters | | |
| Solar panel area [m²]: | 12 × 12 × sin47°/cos20.5° = 112 | 12 × 3 × 2.595 = 93.4 |
| Reflector area [m²]: | 12 × 12 × cos47°/cos20.5° = | NA |
| | 105 | |
| Power generated at noon [kW] | | |
| Spring & Autumn Equinoxes: | 112 × (cos23.5° + 0.95 × sin23.5 | 93.4 × 0.2 = 18.7 |
| | tan43°) × 0.2 = 28.5 (+52%)* | |
| Summer Solstice: | 112 × (cos47° + 0.95 × sin43°) × | 93.4 × 0.2 × cos23.50 = |
| | 0.2 = 29.3 (+71%)* | 17.1 |
| Winter Solstice: | 112 × 0.2 = 22.4 (+31%)* | 93.4 × 0.2 × cos23.50 = 17.1 |
| Solar cell productivity [kW/m²] | | |
| Spring & Autumn Equinoxes: | 0.255 (+27%)* | 0.20 |
| Summer Solstice: | 0.261 (+42%)* | 0.183 |
| Winter Solstice: | 0.200 (+9%)* | 0.183 |

Note:
*the numbers in the parentheses are the differences between the numbers in the first column and those in the second column expressed as percentages of the numbers in the second column.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I claim:

1. A reflector-solar receiver assembly, comprising a reflector and a solar receiver, wherein the reflector has a substantially planar light reflecting face, the solar receiver has a substantially planar light receiving face, and the normal direction of the substantially planar light reflecting face and the normal direction of the substantially planar light receiving face are at an angle of about 90°.

2. The reflector-solar receiver assembly of claim 1, wherein the substantially planar light reflecting face and the substantially planar light receiving face are in contact with each other at a first edge of each of the faces, and the substantially planar light reflecting face and the substantially planar light receiving face form angles of about 47° and about 43°, respectively, with a plane formed by a second edge opposing to the first edge of each of the faces.

3. The reflector-solar receiver assembly of claim 1, comprising two of the reflectors, wherein the normal directions of the substantially planar light reflecting faces of the two of the reflectors are at an angle of about 133°.

4. The reflector-solar receiver assembly of claim 3, comprising two of the solar receivers, wherein the two of the solar receivers are adjacent to each other, and the normal directions of the substantially planar light receiving faces of the two of the solar receivers are at an angle of about 47°.

5. The reflector-solar receiver assembly of claim 4, wherein the substantially planar light receiving faces are in contact with each other, and each of the substantially planar light receiving faces is substantially in contact with each of the substantially planar light reflecting faces, respectively.

6. The reflector-solar receiver assembly of claim 3, further comprising a third reflector having a substantially cylindrical trough-shaped reflecting surface, wherein the third reflector has two edges, each of the two edges is substantially in contact with each of the substantially planar light reflecting faces, respectively, and the curve formed by the light reflecting faces of the three reflectors is substantially smooth, and wherein the solar receiver is a bifacial solar receiver.

7. The reflector-solar receiver assembly of claim 6, wherein the cross section of the third reflector is an arc of about 133°.

8. The reflector-solar receiver assembly of claim 1 wherein the reflector reflects light by internal reflection.

9. The reflector-solar receiver assembly of claim 8, wherein the reflector comprises a clear material having a refractive index of greater than 1.33, and wherein the reflector further comprises a face having parallel ridges, and wherein the solar receiver is a photovoltaic cell, a photovoltaic panel, or a combination thereof.

10. The reflector-solar receiver assembly of claim 9, wherein: a) the normal directions of adjacent facets of the parallel ridges are at an angle of about 90°; b) the normal directions of the two facets of the ridges are also substantially 90° from each other, and c) the substantially planar light reflecting face is about 43° from the facets of the ridges facing away from the substantially planar light receiving face of the solar panel.

11. The reflector-solar receiver assembly of claim 1 being a solar panel-reflector module (SPRM), wherein the SPRM comprises at least two of the reflectors and two of the solar receivers, wherein the solar receivers are photovoltaic cells, photovoltaic panels, or combinations thereof.

12. A method of installing a reflector-solar receiver assembly comprising a reflector that has a substantially planar reflecting face and a solar receiver that has a substantially planar light receiving face at an installation site, the method comprising placing the substantially planar light reflecting face at an angle of about γ−23.5° or about γ+23.5° from the gravitation line of the installation site, where γ is the latitude of the installation site, so that the substantially planar light reflecting face reflects at least a portion of sunlight to the substantially planar light receiving face during a majority of the clear days of a year.

13. A method of installing the reflector-solar receiver assembly of claim 1 at an installation site, comprising placing the normal line of the substantially planar light receiving face at an angle of about γ−23.5° or about γ+23.5° from the gravitation line of the installation site, where γ is the latitude of the installation site; so that the substantially planar light reflecting face reflects at least a portion of sunlight to the substantially planar light receiving face during a majority of the clear days of a year.

14. The method of claim 13, wherein the reflector-solar receiver assembly is a solar panel-reflector module (SPRM), wherein the SPRM is installed such that the normal direction of the SPRM is at an angle greater than 90° and smaller than 180° from that of the gravitational line, so that the light receiving face of the SPRM receives direct sunlight during a majority of the clear days of a year.

15. The method of claim 14, wherein the SPRM is installed on a pitched rooftop.

16. The method of claim 14, wherein the light receiving face of the SPRM is tilted at an angle of about γ−19.5° from the horizontal plane.

17. A method of installing the reflector-solar receiver assembly of claim 3 at an installation site, comprising placing the normal lines of the substantially planar light receiving faces of the two solar receivers at an angle of about γ−23.5° and about γ+23.5°, respectively, from the gravitation line of the installation site, where γ is the latitude of the installation site, so that the substantially planar light reflecting faces of the two light reflectors reflect at least a portion of sunlight to the substantially planar light receiving faces during a majority of the clear days of a year.

18. A method of installing the reflector-solar receiver assembly of claim 5 at an installation site, comprising placing the substantially planar light reflecting faces of the two reflectors at an angle of about γ−23.5° and about γ+23.5°, respectively, from the gravitation line of the installation site, where γ is the latitude of the installation site, so that the substantially planar light reflecting faces of the two light reflectors reflect at least a portion of sunlight to the two substantially planar light receiving faces during a majority of the clear days of a year.

19. The method of installing a reflector-solar receiver assembly of claim 13, wherein the reflector-solar receiver assembly is on a one-dimensional solar tracker.

20. The method of installation a reflector-solar receiver assembly of claim 19, wherein the one-dimensional solar tracker is the polar type or azimuth type.
